(19) United States
(12) Patent Application Publication
(10) Pub. No.: US 2024/0142546 A1
(43) Pub. Date: May 2, 2024

(54) METHOD FOR TESTING AND EVALUATING SHORT-CIRCUIT WITHSTAND CAPABILITY OF PRESS-PACK POWER COMPONENT

(71) Applicant: Chongqing University, Chongqing (CN)

(72) Inventors: Hui LI, Chongqing (CN); Renkuan LIU, Chongqing (CN); Ran YAO, Chongqing (CN); Wei LAI, Chongqing (CN); Zeyu DUAN, Chongqing (CN); Zheyan ZHU, Chongqing (CN); Bailing ZHOU, Chongqing (CN); Siyu CHEN, Chongqing (CN); Jinyuan LI, Chongqing (CN); Zhongyuan CHEN, Chongqing (CN)

(21) Appl. No.: 18/484,486

(22) Filed: Oct. 11, 2023

(30) Foreign Application Priority Data
Nov. 1, 2022 (CN) 202211356605.5

(51) Int. Cl. G01R 31/52; G01R 31/26

(52) U.S. Cl. CPC G01R 31/52; G01R 31/2601; G01R 31/2619

(57) ABSTRACT

Disclosed is a method for testing and evaluating a short-circuit withstand capability of a press-pack power component. The method includes: building a test platform; obtaining a voltage level, a pressure load, an environment temperature, and a maximum junction temperature fluctuation range of a to-be-tested component in an actual working condition; separately testing short-circuit withstand capabilities of the to-be-tested press-pack power component; monitoring, in real time, changes of a component short-circuit current, a collector-emitter voltage, and a grid-emitter voltage until the to-be-tested press-pack power component fails due to short circuit; correspondingly obtaining a relationship between a voltage and each of a short-circuit critical energy and a critical temperature, a relationship between a pressure and a short-circuit current, and a relationship between a temperature and a short-circuit current; obtaining a relationship between a short-circuit withstand capability of the to-be-tested press-pack power component and each of a voltage, a pressure, and a temperature.

### CROSS REFERENCE TO RELATED APPLICATION

This patent application claims the benefit and priority of Chinese Patent Application No. 202211356605.5, filed with the China National Intellectual Property Administration on Nov. 1, 2022, the disclosure of which is incorporated by reference herein in its entirety as part of the present application.

### TECHNICAL FIELD

The present disclosure pertains to the field of power electronics component technologies, and relates to a method for testing and evaluating a short-circuit withstand capability of a press-pack power component.

### BACKGROUND

A short-circuit fault is one of common faults in power electronics equipment. During a short circuit, a power component needs to carry about 5-6 times a rated current in an extremely short time, causing a junction temperature of the component to rise rapidly. If a protection circuit cannot operate within a short-circuit withstand capability of the power component, the power component may be permanently damaged, thereby affecting reliability of the entire system. Therefore, accurately evaluating the short-circuit withstand capability of the power component is a basis for establishing parameters of the protection circuit, which are very important for system reliability.

Currently, a welding package and a crimp package are two mainstream packaging forms of power components. Compared with a welding-packaged power component, a press-pack power component has advantages of short-circuit failure, double-sided heat dissipation, and low thermal resistance. This makes the press-pack power component more suitable for high-voltage and high-power-density applications. However, unlike the welding-packaged power component, the press-pack power component has a complex current-thermal-mechanical coupling relationship inside, and a pressure directly affects a current and a temperature of the component.

However, because the welding-packaged power component has a longer application time and a wider application range, most test and evaluation methods that are currently widely used, including a method for evaluating a short-circuit withstand capability, are formulated based on the welding-packaged power component. In this method, only an internal current-thermal relationship of the welding-packaged power component is considered, and impact of the pressure is not considered. Consequently, an evaluation result is inaccurate when the method is applied to the press-pack power component. Therefore, it is of great importance to invent a novel method for testing and evaluating a short-circuit withstand capability of a press-pack power component, to accurately evaluate a short-circuit withstand capability of the press-pack power component, precisely set the parameters of the protection circuit, and improve system reliability.

### SUMMARY

In view of this, the present disclosure aims to provide a method for testing and evaluating a short-circuit withstand capability of a press-pack power component. The method of the present disclosure resolves a problem of inaccurate evaluation of a short-circuit withstand capability of a press-pack power component by using a conventional test and evaluation method, thereby improving evaluation accuracy of a to-be-tested component.

To achieve the above objective, the present disclosure provides the following technical solutions:

A method for testing and evaluating a short-circuit withstand capability of a press-pack power component specifically includes the following steps:
S1: building a test platform suitable for a short-circuit withstand capability of a press-pack power component;
S2: obtaining a voltage level, a pressure load, an environment temperature, and a maximum junction temperature fluctuation range of a to-be-tested press-pack power component in an actual working condition;
S3: customizing a test scheme of the short-circuit withstand capability, which specifically includes: separately testing short-circuit withstand capabilities of the to-be-tested press-pack power component at different voltages, pressures, and temperature levels; monitoring, in real time, changes of a component short-circuit current I_{S}, a collector-emitter voltage V_{CE}, and a grid-emitter voltage V_{GE} until the to-be-tested press-pack power component fails due to short circuit; and correspondingly obtaining a relationship between a voltage and each of a short-circuit critical energy E_{CR} and a critical temperature T_{CR}, a relationship between a pressure and a short-circuit current, and a relationship between a temperature and a short-circuit current; and
S4: obtaining, according to test results obtained under different voltages, pressures, and temperatures, a relationship between a short-circuit withstand capability of the to-be-tested press-pack power component and each of a voltage, a pressure, and a temperature.

Further, in step S1, the test platform includes a short-circuit energy supply module, a control module, a measurement module, and an environment control module;

the short-circuit energy supply module includes a high-voltage direct current (DC) power supply and a capacitor group that are connected in parallel, to provide impact energy for a short-circuit withstand test;

the control module includes a signal generator and a drive circuit that are connected in series, to control a to-be-tested module to be enabled;

the measurement module includes a voltage probe and a current probe, to monitor and acquire characteristic parameters such as a short-circuit current I_{S}, a collector-emitter voltage V_{CE}, and a grid-emitter voltage V_{GE} in a process of the short-circuit withstand test; and

the environment control module includes a high-voltage DC power supply, a pressure fixture, and a constant-temperature experimental box, to respectively control changes of a voltage, a pressure, and a temperature.

Further, in step S2, a test voltage Uᵢ, a test pressure Fᵢ, and a test temperature Tᵢ are determined according to the actual working condition of the to-be-tested press-pack power component.

The test voltage Uᵢ includes ±10% steps of an actual working voltage U₀ so that testing is performed at voltage levels including U₀−20%, U₀−10%, U₀, U₀+10%, and U₀+20%. According to a specific application condition, a voltage test range may be increased and the step may be reduced.

The test pressure Fᵢ uses a recommended pressure load value F₀ of the to-be-tested press-pack power component in the actual working condition as a reference, and a maximum pressure load value F₀₋ₘₐₓ as an upper limit; within the test pressure Fᵢ∈(0, F₀] interval, testing is performed at least at 5 pressure levels within (0, F₀/2] interval, testing is performed at least at 3 pressure levels; and within the test pressure Fᵢ∈(F₀, F₀₋ₘₐₓ] interval, testing is performed at least at 2 pressure levels. According to a specific application condition, a quantity of test pressure levels may be increased.

The test temperature Tᵢ includes one or more values between T_{EN_min} actual application as a lower limit, and a maximum junction temperature T_{j_max} as an upper limit; where the application working condition includes a minimum value T_{j_min} of junction temperature fluctuation, and testing is performed at least at 4 temperature levels. According to a specific application condition, a quantity of test temperature levels may be increased, and a test temperature range may be appropriately adjusted.

Further, in step S3, a short-circuit current I_{S} and a collector-emitter voltage V_{CE} are monitored in real time in a process of testing the short-circuit withstand capability, and when the short-circuit current I_{S} instantly rises to at least 2 times an initial value and the collector-emitter voltage V_{CE} drops rapidly to about 0 V, it can be determined that the to-be-tested press-pack power component fails due to short circuit.

Further, in step S3, the testing short-circuit withstand capabilities of the to-be-tested press-pack power component at different voltage levels specifically includes: separately testing a short-circuit withstand capability of the to-be-tested press-pack power component at a selected voltage level, and monitoring, in real time, a component short-circuit current Is, a collector-emitter voltage V_{CE}, and a grid-emitter voltage V_{GE} until the to-be-tested press-pack power component fails due to short circuit;
(1) calculating a short-circuit critical energy E_{CR} of the to-be-tested press-pack power component based on the short-circuit current I_{S} and the collector-emitter voltage V_{CE} according to equation:

E_{CR}=∫₀^{t}^{_{SCWC}}V_{CE}(t)·I_{S}(t)·dt, where

t_{SCWC} is a short-circuit withstand time of the to-be-tested press-pack power component, namely, a maintenance time from a beginning of testing to a short-circuit failure of the to-be-tested press-pack power component;
(2) fitting a relationship between a test voltage Uᵢ and a short-circuit critical energy E_{CR} based on the test results at the different voltage levels according to equation:

E_{CR}=f_{E}(Uᵢ), where

f_{E}(Uᵢ) is a fitting relationship function between a test voltage Uᵢ and a short-circuit critical energy E_{CR}; and
(3) obtaining a relationship between a test voltage Uᵢ and a critical temperature T_{CR} according to equation:

$${T}_{CR} ( {U}_{i} ) = \frac{{f}_{E} ( {U}_{i} )}{{K}_{chip}} + {T}_{EN} ,$$

where

K_{chip} is a parameter related to a material and a structure of a chip used by the to-be-tested press-pack power component, and T_{EN} is the environment temperature.

Further, in step S3, the testing short-circuit withstand capabilities of the to-be-tested press-pack power component at different pressure levels specifically includes: separately testing a short-circuit withstand capability of the to-be-tested press-pack power component at a selected pressure level, and monitoring, in real time, changes of a component short-circuit current I_{S}, a collector-emitter voltage V_{CE}, and a grid-emitter voltage V_{GE} until the to-be-tested press-pack power component fails due to short circuit; and

fitting a relationship between a test pressure Fᵢ and a component short-circuit current I_{S} based on the test results at the different pressure levels according to equation:

I_{S}=f(Fᵢ), where

f_{F}(Fᵢ) is a fitting relationship function between the test pressure Fᵢ and the component short-circuit current I_{S}.

Further, in step S3, the testing short-circuit withstand capabilities of the to-be-tested press-pack power component at different temperature levels specifically includes: separately testing a short-circuit withstand capability of the to-be-tested press-pack power component at a selected temperature level, and monitoring, in real time, changes of a component short-circuit current I_{S}, a collector-emitter voltage V_{CE}, and a grid-emitter voltage V_{GE} until the to-be-tested press-pack power component fails due to short circuit; and

fitting a relationship between a temperature Tᵢ and a component short-circuit current I_{S} based on the test results at the different temperature levels according to equation:

I_{S}=Tᵢ^{k}·f_{F}(Fᵢ ), where

k is a parameter related to a characteristic of a chip used by the to-be-tested press-pack power component, and f_{F}(Fᵢ ) is a fitting relationship function between a test pressure Fᵢ and the component short-circuit current I_{S}.

Further, in step S4, an obtained relationship between a short-circuit withstand capability of the to-be-tested press-pack power component and each of a voltage, a pressure, and a temperature is according to equation:

$${t}_{SCWC} = \frac{{K}_{chip} [ {T}_{CR} ( {U}_{i} ) - {T}_{i} ]}{{U}_{i} \cdot {T}_{i}^{k} \cdot {f}_{F} ( {F}_{i} )} ,$$

where

K_{chip} is a parameter related to a material and a structure of a chip used by the to-be-tested press-pack power component, T_{CR} is the critical temperature, Uᵢ is a test voltage, Tᵢ is a test temperature, k is a parameter related to a characteristic of the chip used by the to-be-tested press-pack power component, and f_{F}(Fᵢ ) is a fitting relationship function between a test pressure Fᵢ and the component short-circuit current I_{S}s.

The present disclosure has the following beneficial effects:
(1) The method for testing a short-circuit withstand capability provided in the present disclosure fully considers the application working conditions of the press-pack power component, and comprehensively considers impact of the voltage, the pressure, and the temperature on the short-circuit withstand capability of the press-pack power component. In addition, the test scheme of the short-circuit withstand capability is scientifically optimized according to the application working condition, reducing test difficulty of the short-circuit withstand capability and improving the economic efficiency of testing.
(2) The method for evaluating a short-circuit withstand capability provided in the present disclosure fully considers impact of “current-thermal-mechanical” on the short-circuit withstand capability of the press-pack power component, improving evaluation accuracy of the short-circuit withstand capability of the press-pack power component, helping accurately set parameters of a protection circuit, and improving system reliability.

Other advantages, objectives and features of the present disclosure will be illustrated in the subsequent description in some degree, and will be apparent to those skilled in the art in some degree based on study on the following description, or those skilled in the art may obtain teachings by practicing the present disclosure. The objectives and other advantages of the present disclosure can be implemented and obtained by the description below.

### BRIEF DESCRIPTION OF THE DRAWINGS

In order to make the objectives, technical solutions, and advantages of the present disclosure more clear, the present disclosure will be preferably described in detail below with reference to the accompanying drawings.

FIG. 1 is a flowchart of a method for testing and evaluating a short-circuit withstand capability of a press-pack power component according to the present disclosure.

FIG. 2 is a diagram of a principle of a test platform of a short-circuit withstand capability of a press-pack power component according to the present disclosure.

### DETAILED DESCRIPTION OF THE EMBODIMENTS

The implementations of the present disclosure are described below through specific examples, and those skilled in the art can easily understand other advantages and effects of the present disclosure from the contents disclosed in this specification. The present disclosure can also be implemented or applied through other different specific implementations. Based on different viewpoints and applications, various modifications or amendments can be made to various details of this specification without departing from the spirit of the present disclosure. It should be noted that the diagrams provided in the following embodiments merely illustrate the basic conception of the present disclosure only schematically, and the following embodiments or features in the embodiments may be combined in a non-conflicting manner.

The accompanying drawings are schematic diagrams rather than physical diagrams, which are only for illustrative description and should not be construed as a limitation to the present disclosure. In order to better describe the embodiments of the present disclosure, some components may be omitted, enlarged or reduced in the accompanying drawings, and thus do not represent true sizes of physical products. Those skilled in the art should understand that some well-known structures and descriptions thereof may be omitted in the accompanying drawings.

The same or similar labels in the accompanying drawings of the embodiment of the present disclosure correspond to the same or similar components. In the description of the present disclosure, it should be understood that orientation or position relationships indicated by terms such as “upper”, “lower”, “left”, “right”, “front” and “rear” are orientation or position relationships as shown in the drawings. These terms are merely intended to facilitate and simplify the description of the present disclosure, rather than to indicate or imply that the mentioned device or components must have a specific orientation or must be constructed and operated in a specific orientation. Therefore, the terms describing the positional relationship in the accompanying drawings are only used for illustrative description, and should not be understood as a limitation to the present disclosure. A person of ordinary skill in the art will understand specific meanings of such terms based on a specific situation.

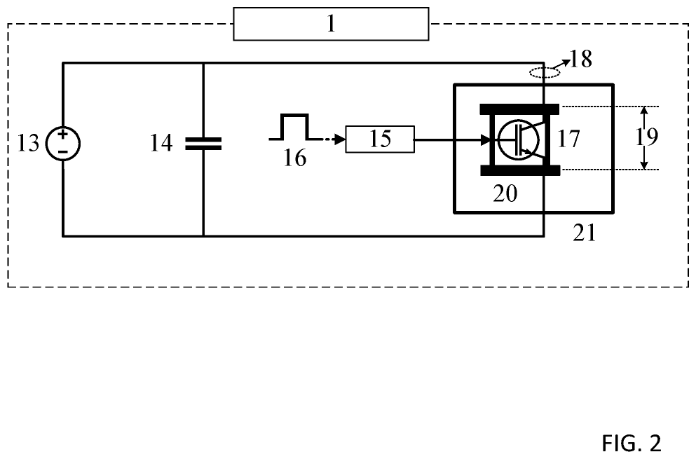

In FIG. 2, 1—test platform of a short-circuit withstand capability of a press-pack power component, 13—High-voltage DC power supply (voltage control), 14—Capacitor group, 15—Drive circuit, 16—Signal generator, 17—To-be-tested component, 18—voltage probe, 19—Current probe, 20—Pressure fixture, 21 Constant-temperature experimental box.

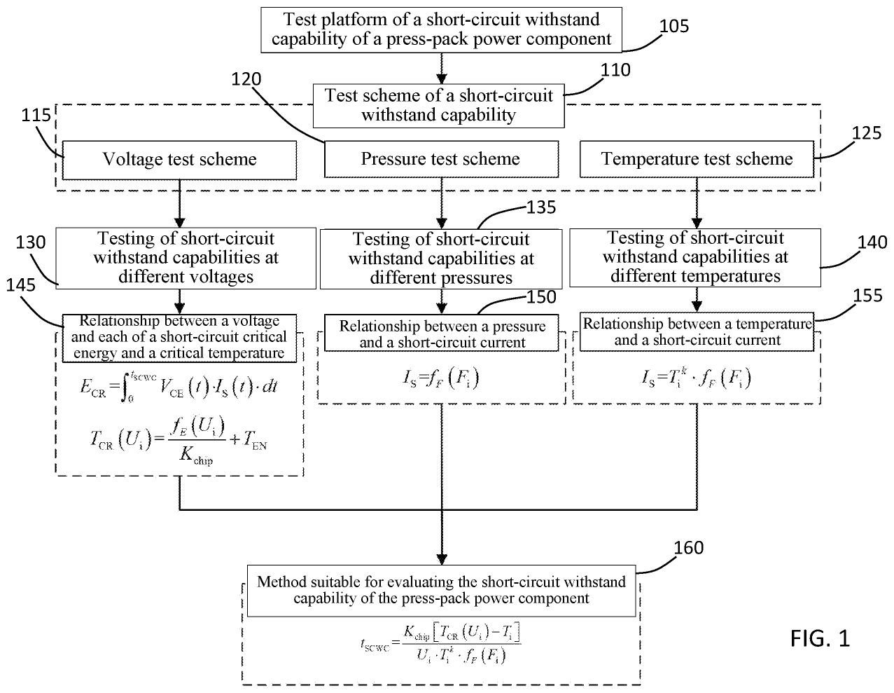

Referring to FIG. 1 and FIG. 2, as shown in FIG. 1, a method 100 for testing and evaluating a short-circuit withstand capability of a press-pack power component provided in the present disclosure includes the following operation steps:

In FIG. 1, the method includes at 105 building a test platform of a short-circuit withstand capability of a press-pack power component. At 110, the method 110 includes implementing a test scheme of a short-circuit withstand capability. The implementing the test scheme of a short-circuit withstand capability includes at 115, implementing a Voltage test scheme, at 120, implementing a Pressure test scheme, and at 125 implementing a Temperature test scheme within a Maximum junction temperature fluctuation range. At 130, the implementing the voltage test scheme includes further includes a Testing of short-circuit withstand capabilities at different voltages. At 135, implementing the pressure test scheme further includes Testing of short-circuit withstand capabilities at different pressures. At 140, implementing the temperature test scheme includes Testing of short-circuit withstand capabilities at different temperatures. At 145, implementing the voltage test scheme includes obtaining a relationship between a test voltage and a short-circuit critical energy E_{CR}, and obtaining a relationship between a test voltage a critical temperature T_{CR}. At 150, the implementing the pressure test scheme includes fitting a relationship between a test pressure and a short-circuit current. At 155, implementing the temperature test scheme further includes obtaining a Relationship between a temperature and a short-circuit current. At 160, the method 100 includes evaluating the short-circuit withstand capability of the press-pack power component using the obtained relationships and results.

The method 100 is discussed in further detail in the context of FIG. 2.

Referring back to 105 of FIG. 1, which involves Establishing a test platform suitable for a short-circuit withstand capability of a press-pack power component. As shown in FIG. 2, the test platform includes a short-circuit energy supply module, a control module, a measurement module, and an environment control module, where

the short-circuit energy supply module includes a high-voltage direct current (DC) power supply and a capacitor group, to provide impact energy for a short-circuit withstand test;

the control module includes a signal generator and a drive circuit, to control a to-be-tested module to be enabled;

the measurement module includes a voltage probe and a current probe, to monitor and acquire characteristic parameters such as a short-circuit current I_{S}, a collector-emitter voltage V_{CE}, and a grid-emitter voltage VGE in a process of the short-circuit withstand test; and

the environment control module includes a high-voltage DC power supply, a pressure fixture, and a constant-temperature experimental box, to respectively control changes of a voltage, a pressure, and a temperature.

The method 100 of FIG. 1 includes steps 115-125 of which involve Obtaining a voltage level, a pressure load, an environment temperature, and a maximum junction temperature fluctuation range of a to-be-tested press-pack power component in an actual working condition, customize a test scheme of the short-circuit withstand capability, and determine a test voltage a test pressure Fᵢ, and a test temperature

The test voltage Uᵢ includes ±10% steps of an actual working voltage U₀ so that testing is performed at voltage levels including U₀−20%, U₀−10%, U₀, U₀+10%, and U₀+20%; According to a specific application condition, a voltage test range may be increased and the step may be reduced. For example, a power component applied in a working condition of 1000 V should be tested at least at 800 V, 900 V, 1000 V, 1100 V, and 1200 V voltage levels.

The test pressure Fᵢ uses a recommended pressure load value F₀ of the to-be-tested press-pack power component in the actual working condition as a reference, and a maximum pressure load value F₀₋ₘₐₓ as an upper limit; within the test pressure Fᵢ∈(0, F₀] interval, testing is performed at least at 5 pressure levels within (0, F₀/2] interval, testing is performed at least at 3 pressure levels; and within the test pressure Fᵢ∈(F₀, F₀₋ₘₐₓ] interval, testing is performed at least at 2 pressure levels. According to a specific application condition, a quantity of test pressure levels may be increased. For example, for a DG50N3300-crimp-typed IGBT component, within the test pressure Fᵢ∈(0, 1000] interval, testing is performed at least at pressure levels of 100 N, 200 N, 500 N, 800 N, and 1000 N. Within the test pressure Fᵢ∈(1000, 2000] interval, testing is performed at least at pressure levels of 1500 N and 2000 N.

The test temperature Tᵢ includes one or more values between T_{EN_min} actual application as a lower limit, and a maximum junction temperature T_{j_max} as an upper limit; where the application working condition includes a minimum value T_{j_ min} of junction temperature fluctuation, and testing is performed at least at 4 temperature levels. According to a specific application condition, a quantity of test temperature levels may be increased, and a test temperature range may be appropriately adjusted. For example, in an application working condition that the minimum environment temperature T_{EN_min} is 25° C., the maximum junction temperature T_{j_max} is 100° C., and the minimum value T_{j_min} of junction temperature fluctuation is 75° C., testing is performed at least at temperature levels of 25° C., 50° C., 75° C., and 100° C.

The method 100 includes step 130, which includes Testing short-circuit withstand capabilities of the to-be-tested press-pack power component at different voltage levels, and monitor, in real time, changes of a component short-circuit current I_{S}, a collector-emitter voltage V_{CE}, and a grid-emitter voltage V_{GE} until the to-be-tested press-pack power component fails due to short circuit; when the short-circuit current I_{S} instantly rises to at least 2 times an initial value and the collector-emitter voltage V_{CE} drops rapidly to about 0 V, it can be determined that the to-be-tested press-pack power component fails due to short circuit.

At 145, the step includes calculating a short-circuit critical energy E_{CR} of the to-be-tested press-pack power component based on the short-circuit current I_{S} and the collector-emitter voltage V_{CE} according to equation:

E_{CR}=∫₀^{t}^{_{SCWC}}V_{CE}(t)·I_{S}(t)·dt, where

t_{SCWC} is a short-circuit withstand time of the to-be-tested press-pack power component, namely, a maintenance time from a beginning of testing to a short-circuit failure of the to-be-tested press-pack power component; fit a relationship between a test voltage Um and a short-circuit critical energy E_{CR} based on test results at the different voltage levels according to equation:

E_{CR}=f_{E}(Uᵢ); and

obtaining a relationship between a test voltage Uᵢ and a critical temperature T_{CR} according to equation:

$${T}_{CR} ( {U}_{i} ) = \frac{{f}_{E} ( {U}_{i} )}{{K}_{chip}} + {T}_{EN} ,$$

where

K_{chip} is a parameter related to a material and a structure of a chip used by the to-be-tested press-pack power component, and T_{EN} is the environment temperature.

At 135, implementing the pressure test scheme 120 includes testing short-circuit withstand capabilities of the to-be-tested press-pack power component at different pressure levels, and monitor, in real time, changes of a component short-circuit current I_{S}, a collector-emitter voltage V_{CE}, and a grid-emitter voltage V_{GE} until the to-be-tested press-pack power component fails due to short circuit; when the short-circuit current I_{S} instantly rises to at least 2 times an initial value and the collector-emitter voltage V_{CE} drops rapidly to about 0 V, it can be determined that the to-be-tested press-pack power component fails due to short circuit; and

At 150 implementing the pressure test scheme includes obtain a relationship between a test pressure F1 and a component short-circuit current I_{S} according to equation:

I_{S}=f_{F}(Fᵢ)

At 140, implementing the temperature test scheme includes testing short-circuit withstand capabilities of the to-be-tested press-pack power component at different temperature levels, and monitor, in real time, changes of a component short-circuit current I_{S}, a collector-emitter voltage V_{CE}, and a grid-emitter voltage V_{GE} until the to-be-tested press-pack power component fails due to short circuit; when the short-circuit current I_{S} instantly rises to at least 2 times an initial value and the collector-emitter voltage V_{CE} drops rapidly to about 0 V, it can be determined that the to-be-tested press-pack power component fails due to short circuit. At 155, implementing the temperature test scheme includes

obtaining a relationship between a temperature Tᵢ and a component short-circuit current I_{S} according to equation:

I_{S}=Tᵢ^{k}f_{F}(Fᵢ), where

k is a parameter related to a characteristic of a chip used by the to-be-tested press-pack power component.

At 160, the method 100 includes evaluating, according to test results obtained under different voltages, pressures, and temperatures, a short-circuit withstand capability of a to-be-tested press-pack power component according to equation:

$${t}_{SCWC} = \frac{{K}_{chip} [ {T}_{CR} ( {U}_{i} ) - {T}_{i} ]}{{U}_{i} \cdot {T}_{i}^{k} \cdot {f}_{F} ( {F}_{i} )}$$

It can be learned from the foregoing description that the method for testing and evaluating a short-circuit withstand capability of a press-pack power component provided in the present disclosure comprehensively considers the application working condition of the to-be-tested press-pack power component, namely, impact of “current-thermal-mechanical”. Compared with a currently widely used method for testing and evaluating a short-circuit withstand capability based on a welding-packaged power component, which only considers impact of “current-thermal”, this method comprehensively considers a package structure and the application working condition of the press-pack power component, thereby improving evaluation accuracy.

It should be noted that the above embodiments are only intended to explain, rather than to limit the technical solutions of the present disclosure. Although the present disclosure is described in detail with reference to the preferred embodiments, those skilled in the art should understand that modifications or equivalent substitutions may be made to the technical solutions of the present disclosure without departing from the spirit and scope of the technical solutions of the present disclosure, and such modifications or equivalent substitutions should be included within the scope of the claims of the present disclosure.

What is claimed is:

1. A method for testing and evaluating a short-circuit withstand capability of a press-pack power component, wherein the method specifically comprises the following steps:
S1: building a test platform suitable for a short-circuit withstand capability of a press-pack power component;
S2: obtaining a voltage level, a pressure load, an environment temperature, and a maximum junction temperature fluctuation range of a to-be-tested press-pack power component in an actual working condition;
S3: customizing a test scheme of the short-circuit withstand capability, which specifically comprises: separately testing short-circuit withstand capabilities of the to-be-tested press-pack power component at different voltage, pressure, and temperature levels; monitoring, in real time, changes of a component short-circuit current I_{S}, a collector-emitter voltage V_{CE}, and a grid-emitter voltage V_{GE} until the to-be-tested press-pack power component fails due to short circuit; and correspondingly obtaining a relationship between a voltage and each of a short-circuit critical energy E_{CR} and a critical temperature T_{CR}, a relationship between a pressure and a short-circuit current, and a relationship between a temperature and a short-circuit current; and
S4: obtaining, according to test results obtained under different voltages, pressures, and temperatures, a relationship between a short-circuit withstand capability of the to-be-tested press-pack power component and each of a voltage, a pressure, and a temperature.

2. The method for testing and evaluating a short-circuit withstand capability of a press-pack power component according to claim 1, wherein in step S1, the test platform comprises a short-circuit energy supply module, a control module, a measurement module, and an environment control module;
the short-circuit energy supply module comprises a high-voltage direct current (DC) power supply and a capacitor group that are connected in parallel, to provide impact energy for a short-circuit withstand test;
the control module comprises a signal generator and a drive circuit that are connected in series, to control a to-be-tested module to be enabled;
the measurement module comprises a voltage probe and a current probe, to monitor and acquire a short-circuit current I_{S}, a collector-emitter voltage V_{CE}, a grid-emitter voltage V_{GE} in a process of the short-circuit withstand test; and
the environment control module comprises a high-voltage DC power supply, a pressure fixture, and a constant-temperature experimental box, to respectively control changes of a voltage, a pressure, and a temperature.

3. The method for testing and evaluating a short-circuit withstand capability of a press-pack power component according to claim 1, wherein in step S2, a test voltage Uᵢ, a test pressure Fᵢ, and a test temperature Tᵢ are determined according to the actual working condition of the to-be-tested press-pack power component, wherein
the test voltage Uᵢ uses an actual working voltage U₀ as a reference, and ±10% as a step, and testing is performed at least at 5 voltage levels, namely, U₀−20%, U₀−10%, U₀, U₀+10%, and U₀+20%;
the test pressure Fᵢ uses a recommended pressure load value F₀ of the to-be-tested press-pack power component in the actual working condition as a reference, and a maximum pressure load value F₀₋ₘₐₓ as an upper limit; within the test pressure Fᵢ∈(0, F₀] interval, testing is performed at least at 5 pressure levels within (0, F₀/2] interval, testing is performed at least at 3 pressure levels; and within the test pressure Fᵢ∈(F₀, F₀₋ₘₐₓ] interval, testing is performed at least at 2 pressure levels; and
the test temperature Tᵢ includes one or more values between T_{EN_min} actual application as a lower limit, and a maximum junction temperature T_{j_max} as an upper limit; a minimum value T_{j_min} of junction temperature fluctuation in the application working condition is comprised, and testing is performed at least at 4 temperature levels.

4. The method for testing and evaluating a short-circuit withstand capability of a press-pack power component according to claim 1, wherein in step S3, a short-circuit current I_{S} and a collector-emitter voltage V_{CE} are monitored in real time in a process of testing the short-circuit withstand capability, and when the short-circuit current I_{S} instantly rises to at least 2 times an initial value and the collector-emitter voltage V_{CE} drops rapidly to about 0 V, it is determined that the to-be-tested press-pack power component fails due to short circuit.

5. The method for testing and evaluating a short-circuit withstand capability of a press-pack power component according to claim 1, wherein in step S3, the testing short-circuit withstand capabilities of the to-be-tested press-pack power component at different voltage levels specifically comprises: separately testing a short-circuit withstand capability of the to-be-tested press-pack power component at a selected voltage level, and monitoring, in real time, a component short-circuit current I_{S}, a collector-emitter voltage V_{CE}, and a grid-emitter voltage V_{GE} until the to-be-tested press-pack power component fails due to short circuit;
(1) calculating a short-circuit critical energy E_{CR} of the to-be-tested press-pack power component based on the short-circuit current I_{S} and the collector-emitter voltage V_{CE}:
E_{CR}=∫₀^{t}^{_{SCWC}}V_{CE}(t)·I_{S}(t)·dt, wherein
t_{SCWC} is a short-circuit withstand time of the to-be-tested press-pack power component, namely, a maintenance time from a beginning of testing to a short-circuit failure of the to-be-tested press-pack power component;
(2) fitting a relationship between a test voltage Uᵢ and a short-circuit critical energy E_{CR} based on the test results at the different voltage levels:
E_{CR}=f_{E}(Uᵢ), wherein
f_{E}(Uᵢ) is a fitting relationship function between a test voltage Uᵢ and a short-circuit critical energy E_{CR}; and
(3) obtaining a relationship between a test voltage Uᵢ and a critical temperature T_{CR}:
$${T}_{CR} ( {U}_{i} ) = \frac{{f}_{E} ( {U}_{i} )}{{K}_{chip}} + {T}_{EN} ,$$
wherein
K_{chip} is a parameter related to a material and a structure of a chip used by the to-be-tested press-pack power component, and T_{EN} is the environment temperature.

6. The method for testing and evaluating a short-circuit withstand capability of a press-pack power component according to claim 1, wherein in step S3, the testing short-circuit withstand capabilities of the to-be-tested press-pack power component at different pressure levels specifically comprises: separately testing a short-circuit withstand capability of the to-be-tested press-pack power component at a selected pressure level, and monitoring, in real time, changes of a component short-circuit current I_{S}, a collector-emitter voltage V_{CE}, and a grid-emitter voltage V_{GE} until the to-be-tested press-pack power component fails due to short circuit; and
fitting a relationship between a test pressure Fᵢ and a component short-circuit current I_{S} based on the test results at the different pressure levels:
I_{S}=f_{F}(Fᵢ), wherein
f_{F}(Fᵢ) is a fitting relationship function between the test pressure Fᵢ and the component short-circuit current I_{S}.

7. The method for testing and evaluating a short-circuit withstand capability of a press-pack power component according to claim 1, wherein in step S3, the testing short-circuit withstand capabilities of the to-be-tested press-pack power component at different temperature levels specifically comprises: separately testing a short-circuit withstand capability of the to-be-tested press-pack power component at a selected temperature level, and monitoring, in real time, changes of a component short-circuit current I_{S}, a collector-emitter voltage V_{CE}, and a grid-emitter voltage V_{GE} until the to-be-tested press-pack power component fails due to short circuit; and
fitting a relationship between a temperature Tᵢ and a component short-circuit current I_{S} based on the test results at the different temperature levels:
I_{S}=Tᵢ^{k}·f_{F}(Fᵢ), wherein
k is a parameter related to a characteristic of a chip used by the to-be-tested press-pack power component, and f_{F}(Fᵢ) is a fitting relationship function between a test pressure Fᵢ and the component short-circuit current I_{S}.

8. The method for testing and evaluating a short-circuit withstand capability of a press-pack power component according to claim 1, wherein in step S4, an obtained relationship between a short-circuit withstand capability of the to-be-tested press-pack power component and each of a voltage, a pressure, and a temperature is:
$${t}_{SCWC} = \frac{{K}_{chip} [ {T}_{CR} ( {U}_{i} ) - {T}_{i} ]}{{U}_{i} \cdot {T}_{i}^{k} \cdot {f}_{F} ( {F}_{i} )} ,$$
wherein
K_{chip} is a parameter related to a material and a structure of a chip used by the to-be-tested press-pack power component, T_{CR} is the critical temperature, Uᵢ is a test voltage, Tᵢ is a test temperature, k is a parameter related to a characteristic of the chip used by the to-be-tested press-pack power component, and f_{F}(Fᵢ) is a fitting relationship function between a test pressure Fᵢ and the component short-circuit current I_{S}.
